(19) United States
(12) Patent Application Publication
(10) Pub. No.: US 2026/0343733 A1
(43) Pub. Date: Oct. 29, 2026

(54) WIRING SUBSTRATE AND METHOD FOR MANUFACTURING WIRING SUBSTRATE

(71) Applicant: IBIDEN CO., LTD., Gifu (JP)

(72) Inventors: Yuki NIWA, Gifu (JP); Hiroyuki KURAHASHI, Gifu (JP); Shogo FUKUI, Gifu (JP)

(73) Assignee: IBIDEN CO., LTD., Gifu (JP)

(21) Appl. No.: 19/404,627

(22) Filed: Dec. 1, 2025

(30) Foreign Application Priority Data
Dec. 13, 2024 (JP) 2024-219029

(51) Int. Cl. H05K 1/02

(52) U.S. Cl. CPC H05K 1/0298; H05K 2201/2081

(57) ABSTRACT

A method for manufacturing a wiring substrate includes laminating an adhesive sheet on a substrate having a circuit pattern region and a frame region surrounding the circuit pattern region, and thermocompression bonding the adhesive sheet to the substrate such that an insulating layer is formed on the substrate. The thermocompression bonding includes applying a first pressure in the circuit pattern region and applying a second pressure in the frame region such that the first pressure in the circuit pattern region is greater than the second pressure in the frame region and that a differential pressure between the first pressure and the second pressure forms a convex portion in the adhesive sheet, and curing the adhesive sheet including the convex portion such that the convex portion is formed in the frame region at a position that is not exposed at an end surface of the insulating layer.

### CROSS-REFERENCE TO RELATED APPLICATIONS

The present application is based upon and claims the benefit of priority to Japanese Patent Application No. 2024-219029, filed Dec. 13, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2024-109372 describes a method for manufacturing a wiring substrate. The entire contents of this publication are incorporated herein by reference.

### SUMMARY OF THE INVENTION

According to one aspect of the present invention, a method for manufacturing a wiring substrate includes laminating an adhesive sheet on a substrate having a circuit pattern region and a frame region surrounding the circuit pattern region, and thermocompression bonding the adhesive sheet to the substrate such that an insulating layer is formed on the substrate. The thermocompression bonding includes applying a first pressure in the circuit pattern region and applying a second pressure in the frame region such that the first pressure in the circuit pattern region is greater than the second pressure in the frame region and that a differential pressure between the first pressure and the second pressure forms a convex portion in the adhesive sheet, and curing the adhesive sheet including the convex portion such that the convex portion is formed in the frame region at a position that is not exposed at an end surface of the insulating layer.

According to another aspect of the present invention, a wiring substrate includes a first insulating layer, and a second insulating layer formed on the first insulating layer.

The first insulating layer has a circuit pattern region, a frame region surrounding the circuit pattern region, and a convex portion formed in the frame region such that the convex portion of the first insulating layer is not exposed from an end surface of the first insulating layer and that the second insulating layer is covering the convex portion of the first insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a partial cross-sectional view illustrating an example of a wiring substrate according to an embodiment of the present invention;

FIG. 2 is a partial cross-sectional view illustrating another example of a wiring substrate according to an embodiment of the present invention;

FIG. 3 is a plan view illustrating an example of a wiring substrate according to an embodiment of the present invention;

FIG. 4A is a cross-sectional view illustrating an example of a wiring substrate being manufactured using a method for manufacturing a wiring substrate according to an embodiment of the present invention;

FIG. 4B is a cross-sectional view illustrating an example of a wiring substrate being manufactured using a method for manufacturing a wiring substrate according to an embodiment of the present invention;

FIG. 4C is a cross-sectional view illustrating an example of a wiring substrate being manufactured using a method for manufacturing a wiring substrate according to an embodiment of the present invention;

FIG. 4D is a cross-sectional view illustrating an example of a wiring substrate being manufactured using a method for manufacturing a wiring substrate according to an embodiment of the present invention;

FIG. 4E is a cross-sectional view illustrating an example of a wiring substrate being manufactured using a method for manufacturing a wiring substrate according to an embodiment of the present invention;

FIG. 4F is a cross-sectional view illustrating an example of a wiring substrate being manufactured using a method for manufacturing a wiring substrate according to an embodiment of the present invention;

FIG. 4G is a cross-sectional view illustrating an example of a wiring substrate being manufactured using a method for manufacturing a wiring substrate according to an embodiment of the present invention;

FIG. 4H is a cross-sectional view illustrating an example of a wiring substrate being manufactured using a method for manufacturing a wiring substrate according to an embodiment of the present invention;

FIG. 4I is a cross-sectional view illustrating an example of a wiring substrate being manufactured using a method for manufacturing a wiring substrate according to an embodiment of the present invention;

FIG. 4J is a cross-sectional view illustrating an example of a wiring substrate being manufactured using a method for manufacturing a wiring substrate according to an embodiment of the present invention; and

FIG. 4K is a cross-sectional view illustrating an example of a wiring substrate being manufactured using a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

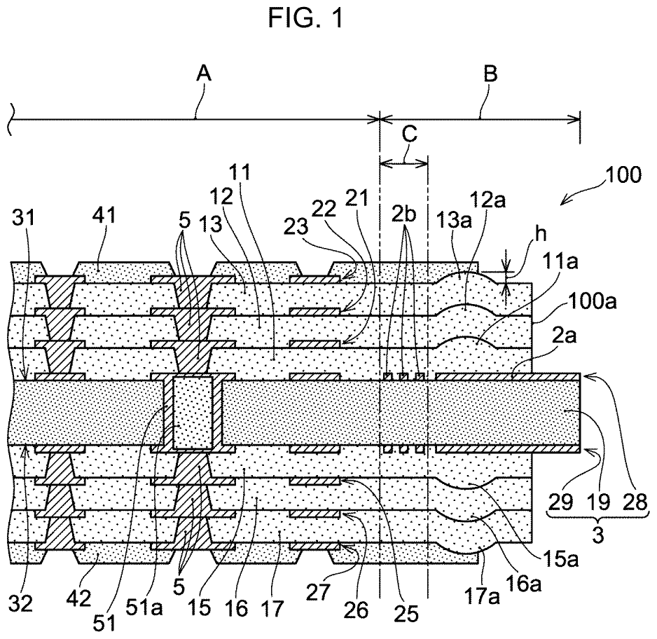

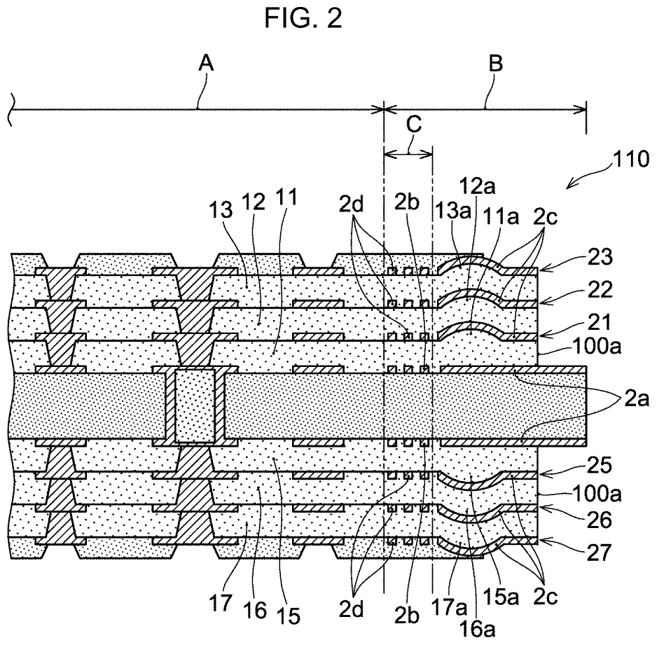

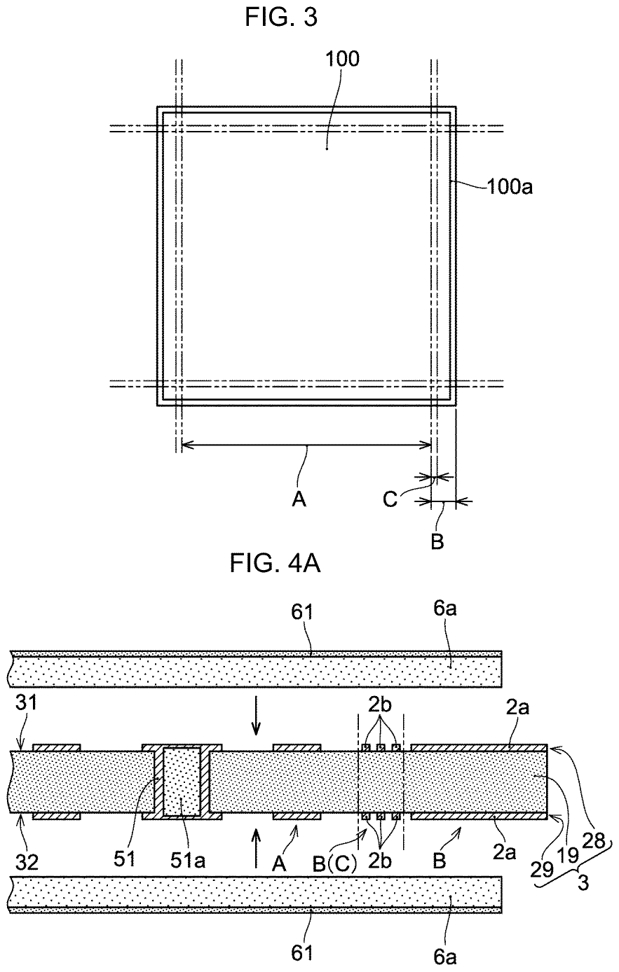

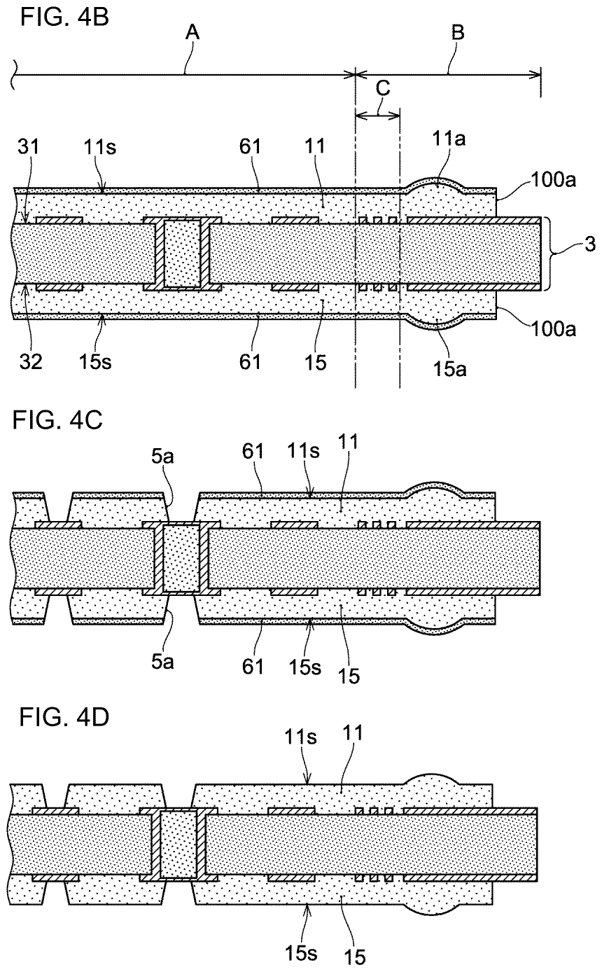

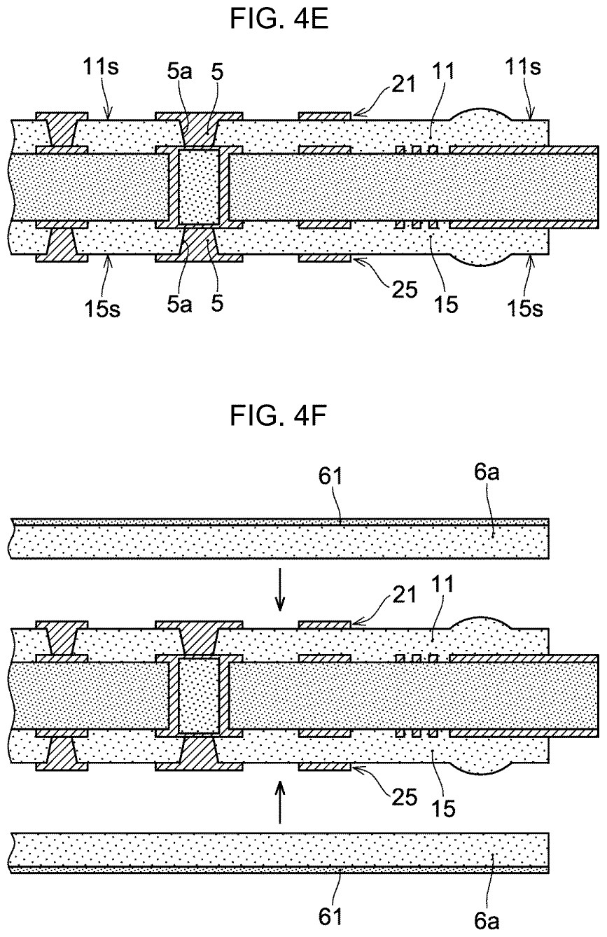

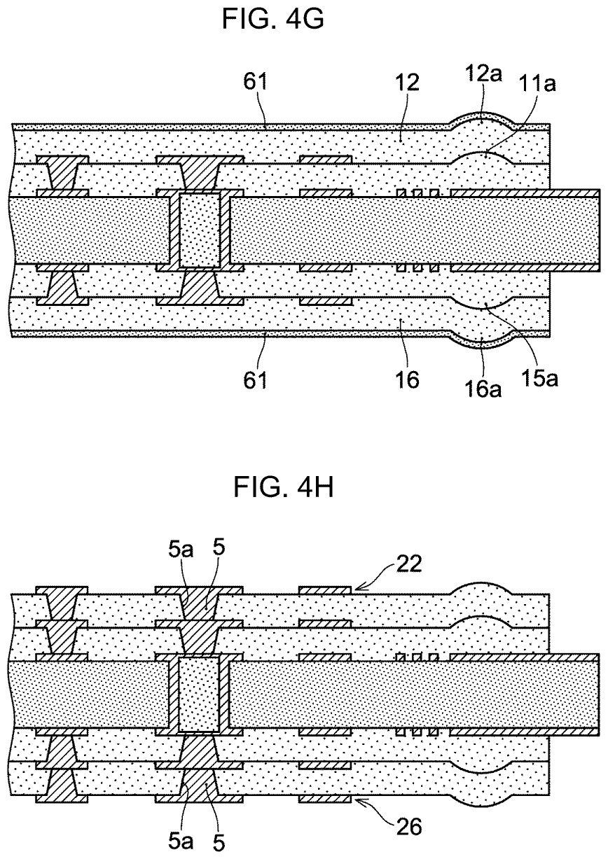

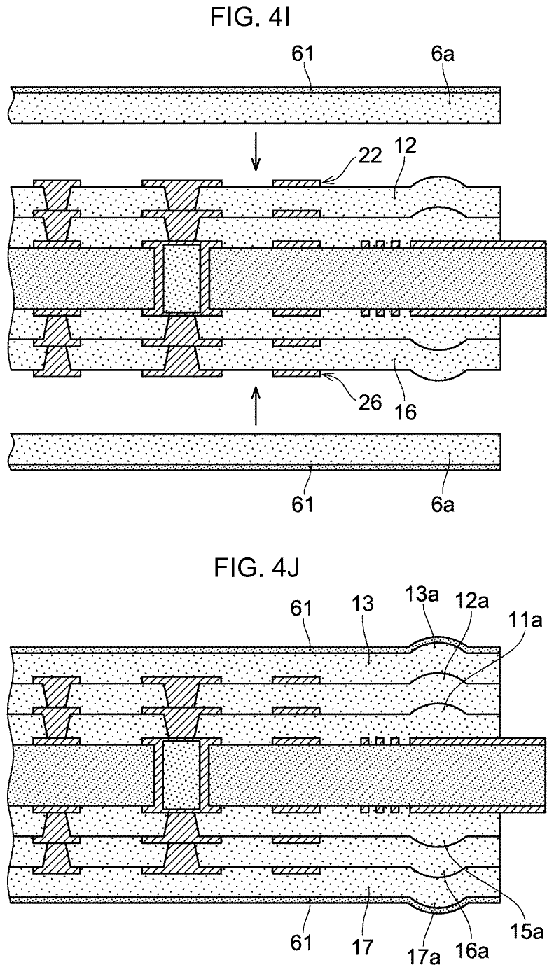

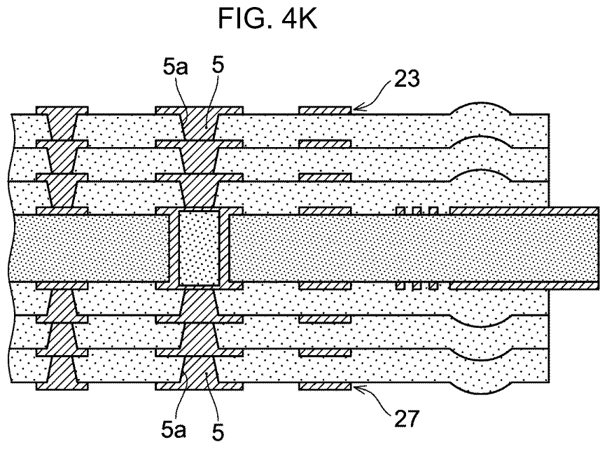

FIGS. 1 and 2 illustrate partial cross-sectional views of wiring substrates (100, 110), which are examples of a wiring substrate according to an embodiment of the present invention. A manufacturing method according to an embodiment of the present invention is illustrated in FIGS. 4A to 4K. As illustrated in FIGS. 1 and 2, the wiring substrates (100, 110) have a circuit pattern region (A) and a frame region (B) formed around the circuit pattern region (A). FIG. 3 is a plan view illustrating the circuit pattern region (A) and the frame region (B) around the circuit pattern region (A) in the wiring substrates (100, 110). The wiring substrates (100, 110) in FIGS. 1 and 2 are merely examples of the wiring substrate of the embodiment. That is, using the method for manufacturing a wiring substrate of the embodiment, it is possible to manufacture a wiring substrate having a structure different from the laminated structures of the wiring substrates (100, 110) and/or including a different number of resin insulating layers and wiring layers from the number of wiring layers and resin insulating layers of the wiring substrates (100, 110). In the drawings to be referenced in the following description, in order to facilitate understanding of an embodiment to be disclosed, a specific portion may be depicted in an enlarged manner and it may be possible that structural elements are not depicted in precise proportions in terms of size or length relative to each other.

As illustrated in FIG. 1, the wiring substrate 100 includes a core substrate 3 and, sequentially laminated on a first surface 31 of the core substrate 3, a resin insulating layer 11, a wiring layer 21, a resin insulating layer 12, a wiring layer 22, a resin insulating layer 13, a wiring layer 23, and a solder resist 41. Further, the wiring substrate 100 includes, sequentially formed on a second surface 32 of the core substrate 3, a resin insulating layer 15, a wiring layer 25, a resin insulating layer 16, a wiring layer 26, a resin insulating layer 17, a wiring layer 27, and a solder resist 42 (a “resin insulating layer” is hereinafter also referred to simply as an “insulating layer”). The core substrate 3 is formed of an insulating layer 19 and wiring layers (28, 29) formed respectively on both surfaces of the insulating layer 19. In the core substrate 3, a through-hole conductor 51 that penetrates the insulating layer 19 and connects the wiring layers (28, 29) is formed. An interior of the tubular through-hole conductor 51 is filled with a filler (51a) formed of an epoxy resin or the like.

In the following description of the method for manufacturing a wiring substrate of the embodiment, in a thickness direction (lamination direction) of the wiring substrate 100, a side farther from the insulating layer 19 is also referred to as an “outer side,” “upper side,” “upward,” or simply “upper,” and a side closer to the insulating layer 19 is also referred to as an “inner side,” “lower side,” “downward,” or simply “lower.” Further, for the structural elements such as a wiring layer or an insulating layer, a surface facing an opposite side with respect to the insulating layer 19 is also referred to as an “upper surface,” and a surface facing the insulating layer 19 is also referred to as a “lower surface.” Via conductors 5 are formed in the insulating layers (11-13, 15-17), penetrating the respective insulating layers and connecting the wiring layers on both sides of each insulating layer. The wiring layers (21-23, 25-27, 28, 29) each include any desired conductor patterns, such as wiring patterns or conductor pads. In the example of FIG. 1, the wiring layer 28 and the wiring layer 29 each include dummy patterns (2a, 2b) in the frame region (B).

The insulating layers (11-13, 15-17, 19) can each be formed using an insulating resin. Examples of the insulating resin include thermosetting resins such as epoxy resin, bismaleimide triazine (BT) resin, or phenol resin; and thermoplastic resins such as fluororesin, liquid crystal polymer (LCP), polytetrafluoroethylene (PTFE) resin, polyester (PE) resin, and modified polyimide (MPI) resin. On the other hand, the solder resists (41, 42) can be formed, for example, using a photosensitive epoxy resin or polyimide resin.

The insulating layers (11-13, 15-17, 19) can each contain an inorganic filler (not illustrated), such as silica or alumina, and/or a reinforcing material (core material) made of glass fiber or the like (not illustrated).

The wiring layers (21-23, 25-27, 28, 29), via conductors 5, and through-hole conductor 51 are formed, for example, using any metal such as copper or nickel.

Although these are simplified and depicted in FIG. 1 as each having only a single layer, they can each have, for example, a multilayer structure of two or more layers including an electroless plating film or sputtering film and an electrolytic plating film.

The wiring layers (28, 29) include the dummy patterns (2a) and the dummy patterns (2b). The dummy patterns (2b) are formed in a region on the circuit pattern region (A) side of the dummy patterns (2a) in the frame region (B). In the example illustrated in FIG. 1, the dummy patterns (2a) are solid patterns, and the dummy patterns (2b) are formed as mesh patterns.

The insulating layers (11-13, 15-17) do not extend to an outer edge of the frame region (B) and are missing over a portion on the outer edge side of the dummy patterns (2a). That is, in the wiring substrate 100, the insulating layers (11-13, 15-17) form an end surface (100a) on an inner side of the outer edge of the frame region (B) such that an edge portion of the core substrate 3 is exposed. The insulating layers (11-13, 15-17) respectively include convex portions (11a-13a, 15a-17a) that bulge in a direction away from the core substrate 3 in the frame region (B) of the wiring substrate 100. The convex portions (11a-13a, 15a-17a) are formed in a region of the frame region (B) where the dummy patterns (2a) are formed. However, the convex portions (11a-13a, 15a-17a) are not exposed at the end surface (100a). The convex portions (11a-13a, 15a-17a) are formed away from the end surface (100a). As illustrated in FIG. 1, the insulating layers (11-13, 15-17) have flat portions between the convex portions (11a-13a, 15a-17a) and the end surface (100a). Heights (h) of the convex portions (11a-13a, 15a-17a) from the respective flat portions are, for example, 15 μm or less. The convex portions (11a-13a, 15a-17a) can have similar heights (h).

The insulating layers (11-13, 15-17) on the dummy patterns (2b) are each formed to be substantially flat. A region in the frame region (B) where the dummy patterns (2b) are formed is also referred to as an adjustment region (C). The convex portions (11a-13a, 15a-17a) are formed with the adjustment region (C) interposed between the circuit pattern region (A) and the convex portions.

As illustrated in FIG. 3, the circuit pattern region (A) is surrounded by the frame region (B). Specifically, the circuit pattern region (A) is surrounded by the adjustment region (C), which is a part of the frame region (B). The wiring substrate 100 has the end surface (100a) on an inner side of the outer edge of the frame region (B).

The solder resist 41 is formed on the resin insulating layer 13 and the wiring layer 23. As illustrated in FIG. 1, the solder resist 41 does not extend to the end surface (100a) and only partially covers the convex portion (13a). The solder resist 42 is formed on the resin insulating layer 17 and the wiring layer 27. As illustrated in FIG. 1, the solder resist 42 does not extend to the end surface (100a) and only partially covers the convex portion (17a). Thicknesses of the solder resists (41, 42) are greater than the heights (h) of the convex portions (13a, 17a).

FIG. 2 illustrates the wiring substrate 110 as another example of a wiring substrate manufactured using the manufacturing method of the embodiment. In the wiring layers (21-23, 25-27) of the wiring substrate 110, dummy patterns (2c), which are solid patterns, are formed in the frame region (B) excluding the adjustment region (C). The dummy patterns (2c) are formed on the respective insulating layers (11-13, 15-17) at positions overlapping with the dummy patterns (2a) in plan view, extending to the end surface (100a). Here, the term “plan view” means viewing an object along a thickness direction of the wiring substrate 110. That is, the dummy patterns (2c) respectively cover entire surfaces of the convex portions (11a-13a, 15a-17a). In the adjustment region (C) of the wiring substrate 110, dummy patterns (2d), which are mesh patterns similar to the dummy patterns (2b), are formed on the respective insulating layers (11-13, 15-17).

On the resin insulating layer 13 and the wiring layer 23, as well as on the resin insulating layer 17 and the wiring layer 27 of the wiring substrate 110, solder resists (41, 42) are respectively formed in the same manner as in the wiring substrate 100. The solder resist 41 partially covers the dummy pattern (2c) laminated on the convex portion (13a).

The solder resist 42 partially covers the dummy pattern (2c) laminated on the convex portion (17a). A combined thickness of the height (h) of each of the convex portions (13a, 17a) (see FIG. 1) and a thickness of each dummy pattern (2c) is smaller than a thickness of each of the solder resists (41, 42).

Using a case where the wiring substrate 100 illustrated in FIG. 1 is manufactured as an example, a method for manufacturing a wiring substrate of the embodiment is described with reference to FIGS. 4A-4K.

As illustrated in FIGS. 4A and 4B, the method for manufacturing a wiring substrate of the present embodiment includes laminating a semi-cured insulating layer 11 having a support film 61 on its surface (11s) onto a substrate (in the example of FIG. 4A, the core substrate 3). When the wiring substrate 100 of FIG. 1 is manufactured, the core substrate 3 is prepared, and the insulating layer 11 is laminated on the first surface 31 of the core substrate 3, and the insulating layer 15 is laminated on the second surface 32 of the core substrate 3. The core substrate 3 has the circuit pattern region (A) where circuit patterns are densely formed, and the frame region (B) surrounding the circuit pattern region (A).

The frame region (B) includes, on the side toward the circuit pattern region (A), an adjustment region (C). Further, laminating the insulating layer 11 can include, as illustrated in FIG. 4A, laminating an adhesive sheet (6a) onto a prepared substrate such as the core substrate 3.

A substrate to serve as a base for the insulating layer 11, such as the core substrate 3, is prepared using any suitable method. For example, when the core substrate 3 is prepared, a double-sided copper-clad laminate including an insulating layer that will serve as the insulating layer 19 and metal foils bonded to both surfaces of the insulating layer is prepared. After forming a through hole by drilling, the through-hole conductor 51 is formed in the through hole by electroless plating and electrolytic plating. The filler (51a) is formed by filling the interior of the through-hole conductor 51 with an epoxy resin or the like, and then, the wiring layers (28, 29) including predetermined conductor patterns such as the dummy patterns (2a) and the dummy patterns (2b) are formed, for example, using a subtractive method including electroless plating and electrolytic plating. The dummy patterns (2a) are formed in the frame region (B) excluding the adjustment region (C). The dummy patterns (2b) are formed in the adjustment region (C). For example, in this manner, the core substrate 3 including the wiring layers (28, 29) and the insulating layer 19 is prepared. The substrate prepared as a base for an insulating layer such as the insulating layer 11 may be a support substrate. Further, the substrate to serve as a base is not necessarily a so-called core substrate, and may be, for example, a single insulating layer or a laminate of an insulating layer and a wiring layer that has already been formed using a build-up method.

As illustrated in FIG. 4A, the adhesive sheet (6a) has, on its surface, the support film 61 that is provided releasably from the adhesive sheet. The support film 61 also functions as a protective film when a through hole (5a) is formed in a later process. The adhesive sheet (6a) having the support film 61 is laminated on each of the first surface 31 and the second surface 32 of the core substrate 3. In the example illustrated in FIG. 4A, the adhesive sheet (6a) and the support film 61 are smaller than the core substrate 3 in plan view.

The adhesive sheet (6a) is, for example, a resin film and is formed of a material containing any of the resins described above as materials for the insulating layers (11, 15), such as a thermosetting resin (such as an epoxy resin) or a thermoplastic resin (such as a fluororesin). The adhesive sheet (6a) can contain these resins in a so-called B-stage state, which is a semi-cured or dried state. An example of a material for the support film 61 is polyethylene terephthalate (PET). However, the material for the support film 61 is not limited to PET.

After being laminated on the core substrate 3, the adhesive sheet (6a) is heated and pressed together with the support film 61. As a result, the adhesive sheets (6a) laminated on both surfaces of the core substrate 3 are respectively thermocompression-bonded to the core substrate 3, and the insulating layer 11 or the insulating layer 15 is formed on each surface of the core substrate 3. The surface (11s) of the insulating layer 11 and a surface (15s) of the insulating layer 15 are respectively covered with the support films 61, which also function as protective films.

In thermocompression bonding the adhesive sheet (6a) (see FIG. 4A), the resin constituting the adhesive sheet (6a) is softened by heating and pressed toward the first surface 31 or the second surface 32 of the core substrate 3 by a pressing plate. In the method for manufacturing a wiring substrate of the present embodiment, a pressing plate having a recess at a position corresponding to the position where the convex portion (11a) or the convex portion (15a) (see FIG. 4B) is to be formed can be used in a thermocompression bonding process. By allowing the softened resin of the adhesive sheet (6a) and the support film 61 to flow into the recess of the pressing plate, a resin layer (the insulating layer 11 or the insulating layer 15) in a semi-cured state having a raised portion that forms the convex portion (11a) or the convex portion (15a) of the insulating layer 11 £ or the insulating layer 15 is formed. The raised portion is composed of the semi-cured resin and the support film 61 on the resin.

During the thermocompression bonding of the adhesive sheet (6a) (see FIG. 4A), the pressure applied to the wiring substrate 100 by the pressing plate can differ between the circuit pattern region (A) located at a central portion of the wiring substrate 100 and the frame region (B) surrounding the circuit pattern region (A). In the circuit pattern region (A) located at the central portion of the wiring substrate 100, circuit patterns are densely formed in the wiring layers (28, 29) and the pressing plate has a flat surface, and thus, a relatively large first pressure can be applied to the wiring substrate 100. On the other hand, in the frame region (B) on an outer side of the circuit pattern region (A), the dummy patterns (2b), which are mesh patterns, are formed in the adjustment region (C), and the pressing plate includes a recess on an outer side of the adjustment region (C).

Therefore, by pressing with the pressing plate, a second pressure smaller than the first pressure applied in the circuit pattern region (A) can be applied in the frame region (B).

Specifically, during pressing with the pressing plate, the softened resin of the adhesive sheet (6a) and the support film 61 are pressed and spread from the central portion toward the outer edge of the frame region (B), where the second pressure smaller than the first pressure is applied, by the first pressure applied to the central portion of the wiring substrate 100. The softened resin and the support film 61 that flow outward accumulate in the adjustment region (C), where the pressure applied by the pressing plate is smaller, and thereafter further flow outward into the recess of the pressing plate. It is thought that in the adjustment region (C), the differential pressure between the first and second pressures and the dummy patterns (2b) formed relatively sparsely in the wiring layers (28, 29) reduce the flow rate, thereby allowing the resin and the support film 61 to efficiently flow into the recess of the pressing plate.

Instead of a pressing plate having a recess, an adhesive sheet (6a) having a recess formed in the support film 61 may be used. In this case, by pressing with the pressing plate, the softened resin of the adhesive sheet (6a) flows into the recess provided in the support film 61, and a semi-cured resin layer (the insulating layer 11 or the insulating layer 15) having a raised portion that forms the convex portion (11a) or the convex portion (15a) of the insulating layer 11 or the insulating layer 15 is formed.

After the thermocompression bonding of the adhesive sheet (6a), the semi-cured insulating layer 11 or insulating layer 15 is fully cured. By the full curing, the resin constituting the insulating layer 11 or the insulating layer 15 is cured to a final stage of curing, a so-called C-stage state. The insulating layers (11, 15) are fully cured, for example, by heating at a temperature suitable for fully curing the resin constituting the insulating layers (11, 15) for an appropriate time. Without being limited to thermal curing, the insulating layers (11, 15) may be fully cured using any other method such as ultraviolet irradiation. The insulating layers (11, 15) having the convex portions (11a, 15a) and having the surfaces (11s, 15s) covered with the support films 61 are formed.

The convex portions (11a, 15a) are located in a region of the frame region (B) where the dummy patterns (2a) are formed, away from the end surface (100a). That is, the convex portions (11a, 15a) are formed at positions such that flat portions exist between the convex portions (11a, 15a) and the end surface (100a), where the insulating layers are formed substantially flat. Forming the convex portions (11a, 15a) at such positions prevents the softened resin of the adhesive sheet (6a) from spreading beyond the position where the end surface (100a) is formed to the edge portion of the core substrate 3 on an outer side. It is thought that when the resin flows to an outer side of the support film 61 and reaches the edge portion of the core substrate 3, the resin bulges in a direction opposite to the core substrate 3 due to surface tension. Therefore, there is a risk that a part of the resin near the edge portion of the core substrate 3 may bulge so as to cover the surface of the support film 61, or that an insulating layer having a shape excessively raised compared to the surface (11s) of the insulating layer 11 or the surface (15s) of the insulating layer 15 is formed. It is thought that skiving processing to remove the raised portion or flattening treatment of the insulating layer would be required, and production efficiency would be reduced.

By forming the convex portions (11a, 15a) at positions away from the end surface (100a), the convex portions (11a, 15a) can be made to have a gentle shape. As described above, when a raised portion is formed at the edge portion of the core substrate 3, the raised portion tends to have a steep shape. When such a raised portion is formed, not only does a large thickness variation occur in the insulating layer from the edge portion of the core substrate 3 to the frame region (B), but this variation may also cause deterioration in the flatness of the portion of the insulating layer extending from the frame region (B) to a central portion of the circuit pattern region (A). It is thought that deterioration in flatness leads to a decrease in yield. Forming the convex portions (11a, 15a) in a gentle shape is thought to suppress thickness variation in the insulating layers and, as a result, produce insulating layers with improved flatness. It is thought that subsequent lamination of the wiring layers (21, 25) (see FIG. 4E) and resin layers can be appropriately performed.

In the method for manufacturing a wiring substrate of the present embodiment, since a flat adjustment region (C) is formed in the frame region (B), the influence of the convex portions (11a, 15a) on the thickness of the insulating layers in the circuit pattern region (A) is reduced. It is thought that in the circuit pattern region (A), insulating layers (11, 15) having excellent flatness are formed.

Next, as illustrated in FIG. 4C, via through holes (5a) for forming the via conductors 5 (see FIG. 1) are formed in each of the insulating layer 11 and the insulating layer 15, penetrating the respective insulating layers (11, 15). The through holes (5a) are formed, for example, by irradiation with laser such as CO₂ laser or UV laser. In the example illustrated in FIG. 4C, the through holes (5a) are formed in the insulating layers (11, 15) with the support films 61 still attached. That is, the through holes (5a) are formed penetrating the support films 61 together with the respective insulating layers (11, 15) with the support films 61 still attached. Since the support films 61 remain attached, adhesion of resin debris generated from the insulating layers (11, 15) to the surface (11s) of the insulating layer 11 or the surface (15s) of the insulating layer 15 is prevented during the formation of the through holes (5a). Further, since an irradiation surface for laser processing is a surface of the support film 61 rather than the surfaces (11s, 15s), excessive formation of the through holes (5a) in the insulating layer 11 or the insulating layer 15 due to impact during irradiation is prevented.

A resin residue removal treatment (so-called desmear treatment) for removing resin residues generated during the formation of the through holes (5a) may be performed in the through holes (5a). The resin residue removal treatment is performed while the insulating layer 11 and the insulating layer 15 remain provided with the support films 61. It is thought that the surface (11s) of the insulating layer 11 and the surface (15s) of the insulating layer 15 are prevented from being subjected to any chemical and/or mechanical stress.

The removal treatment may be, for example, a wet process including immersion in a dissolving solution such as a permanganate solution. Alternatively, the removal treatment may be a dry process that does not use a dissolving solution. A dry process for removing resin residues may be, for example, a plasma treatment using a plasma gas such as argon, tetrafluoromethane, a mixed gas of tetrafluoromethane and oxygen, or sulfur hexafluoride.

Thereafter, the support films 61 are removed. The support films 61 may be removed using any method, and for example, the support films 61 may be peeled from the respective insulating layers (11, 15) by simply pulling the support films 61 in directions opposite to the insulating layers (11, 15). Further, the support films 61 may be removed by dissolution using an appropriate solvent.

By removing the support films 61, as illustrated in FIG. 4D, the surface (11s) of the insulating layer 11 and the surface (15s) of the insulating layer 15 are exposed. Since the surfaces were protected by the support films 61, clean and non-roughened surfaces (11s, 15s) are exposed that have no adhesion of resin debris or the like and have little stress history in the processes up to this point.

Next, as illustrated in FIG. 4E, the wiring layer 21 is formed on the exposed surface (11s) of the insulating layer 11. The wiring layer 25 is formed on the surface (15s) of the insulating layer 15. Further, the via conductors 5 integrated with the wiring layer 21 are formed in the through holes (5a) penetrating the insulating layer 11. The via conductors 5 integrated with the wiring layer 25 are formed in the through holes (5a) penetrating the insulating layer 15.

The wiring layers (21, 25) and via conductors 5 can be formed using any method for forming wiring layers and via conductors. For example, the wiring layers (21, 25) and via conductors 5 may be formed using a semi-additive method. That is, a seed layer (not illustrated) made of a metal film such as copper is formed by electroless plating or sputtering on the surfaces (11s, 15s) of the insulating layers and in the through holes (5a). On the formed seed layer, a plating resist (not illustrated) having appropriate openings is formed, and an electrolytic plating film (not illustrated) is formed in the openings of the plating resist using the seed layer as a power feeding layer. The via conductors 5 are formed in the through holes (5a). Then, the wiring layers (21, 25) having desired conductor patterns are formed by peeling off the plating resist and removing exposed portions of the seed layer by quick etching or the like.

Subsequently, as illustrated in FIGS. 4F and 4G, an adhesive sheet (6a) provided with a support film 61 is thermocompression-bonded onto the insulating layer 11 and the wiring layer 21, and onto the insulating layer 15 and the wiring layer 25, in the same manner as described with reference to FIG. 4A. In the same manner as described for the formation of the insulating layers (11, 15), the semi-cured resin is fully cured, thereby forming the insulating layers (12, 16) each provided with a support film 61. In the insulating layer 12, the convex portion (12a) having substantially the same size as the convex portion (11a) is formed at a position overlapping with the convex portion (11a) in plan view. In the insulating layer 16, the convex portion (16a) having substantially the same size as the convex portion (15a) is formed at a position overlapping with the convex portion (15a) in plan view.

Next, as illustrated in FIG. 4H, the through holes (5a) are formed, the support films 61 (see FIG. 4G) are removed, and the wiring layers (22, 26) having desired conductor patterns and the via conductors 5 are formed, in the same manner as described with reference to FIGS. 4C, 4D and 4E.

Subsequently, as illustrated in FIGS. 4I and 4J, an adhesive sheet (6a) provided with a support film 61 is thermocompression-bonded onto the insulating layer 12 and the wiring layer 22, and onto the insulating layer 16 and the wiring layer 26, in the same manner as described with reference to FIGS. 4A and 4F. Then, in the same manner as described for the formation of the insulating layers (11, 15) and the insulating layers (12, 16) described earlier, the semi-cured resin is fully cured to form the insulating layers (13, 17), each provided with the support film 61. In the insulating layer 13, the convex portion (13a) having substantially the same size as the convex portions (11a, 12a) is formed at a position overlapping the convex portions (11a, 12a) in plan view. In the insulating layer 17, the convex portion (17a) having substantially the same size as the convex portions (15a, 16a) is formed at a position overlapping the convex portions (15a, 16a) in plan view.

Next, as illustrated in FIG. 4K, the through holes (5a) are formed, the support films 61 (see FIG. 4J) are removed, and the wiring layers (23, 27) having desired conductor patterns and the via conductors 5 are formed in the same manner as described with reference to FIGS. 4C, 4D and 4E.

After that, as illustrated in FIG. 1, the solder resist 41 is formed on the insulating layer 13 and the wiring layer 23, and the solder resist 42 is formed on the insulating layer 17 and the wiring layer 27. The solder resists (41, 42) are formed, for example, by supplying a photosensitive epoxy resin or polyimide resin onto the insulating layer and the wiring layer on each side using a method such as lamination or spraying.

In the wiring substrate 100, as illustrated in FIG. 1, the convex portions (13a, 17a) are formed in the frame regions (B) of the resin insulating layers 13 and 17. Therefore, it is thought that during the formation of the solder resists, spreading of the resin forming the solder resists toward the outer edge of the frame region (B) can be suppressed by the convex portions (13a, 17a).

As illustrated in FIG. 1, openings each exposing a portion of the wiring layer 23 or the wiring layer 27 are formed in the solder resists (41, 42) by photolithography or laser irradiation. Through the above processes, the wiring substrate 100 illustrated in FIG. 1 is obtained.

The method for manufacturing the wiring substrate of the embodiment is not limited the method described with reference to the drawings. Further, it is also possible that, using the method for manufacturing a wiring substrate of the embodiment, a wiring substrate having a structure different from the laminated structure illustrated in the drawings or a wiring substrate including a different number of wiring layers from that illustrated in the drawings is manufactured. For example, a wiring substrate that does not include a core substrate may be manufactured using the method for manufacturing a wiring substrate of the embodiment. Further, the wiring substrate may omit the adjustment region (C). In the wiring substrate illustrated in FIG. 2, all of the wiring layers from the second layer onward may omit the dummy patterns (2c) or the dummy patterns (2d). The circuit pattern region (A) may include one or more continuous product areas. A laminate including one wiring substrate in each product area may be formed. Wiring substrates may be manufactured by dividing the formed laminate for the respective product areas. In the method for manufacturing a wiring substrate of the embodiment, it is also possible that any process other than the processes described above is added, or some of the processes described above are omitted.

Japanese Patent Application Laid-Open Publication No. 2024-109372 describes a method for manufacturing a wiring substrate that includes: laminating a resin insulating layer having a protective film on a surface thereof on a substrate; and, while the resin insulating layer remains provided with the protective film, removing a portion of the resin insulating layer that protrudes beyond an outer edge of the protective film using a dissolving agent.

In the method described in Japanese Patent Application Laid-Open Publication No. 2024-109372, an additional process of removing a portion of the resin insulating layer that protrudes beyond the outer edge of the protective film is required, which may reduce production efficiency of the wiring substrate.

A method for manufacturing a wiring substrate according to an embodiment of the present invention is a method for manufacturing a wiring substrate that has a circuit pattern region and a frame region surrounding the circuit pattern region. The method includes: laminating an adhesive sheet on a substrate in the circuit pattern region and the frame region; and forming a first insulating layer on the substrate by thermocompression bonding the adhesive sheet to the substrate by heating and pressing. A first pressure during the thermocompression bonding in the circuit pattern region is greater than a second pressure during the thermocompression bonding in the frame region. The thermocompression bonding includes forming a first convex portion in the adhesive sheet by a differential pressure between the first pressure and the second pressure. The forming of the first insulating layer includes curing the adhesive sheet including the first convex portion by heating. The first convex portion is formed in the frame region at a position that is not exposed at an end surface of the first insulating layer.

A wiring substrate according to an embodiment of the present invention has a circuit pattern region and a frame region surrounding the circuit pattern region. The wiring substrate includes: a first insulating layer; and a second insulating layer on the first insulating layer. The first insulating layer has a first convex portion that is formed in the frame region and is not exposed from an end surface of the wiring substrate. The second insulating layer covers the first convex portion.

According to an embodiment of the present invention, a wiring substrate having improved flatness from an end surface of a resin insulating layer of the wiring substrate to a central portion of a product area can be manufactured with good yield.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
laminating an adhesive sheet on a substrate having a circuit pattern region and a frame region surrounding the circuit pattern region; and
thermocompression bonding the adhesive sheet to the substrate such that an insulating layer is formed on the substrate,
wherein the thermocompression bonding includes applying a first pressure in the circuit pattern region and applying a second pressure in the frame region such that the first pressure in the circuit pattern region is greater than the second pressure in the frame region and that a differential pressure between the first pressure and the second pressure forms a convex portion in the adhesive sheet, and curing the adhesive sheet including the convex portion such that the convex portion is formed in the frame region at a position that is not exposed at an end surface of the insulating layer.

2. The method for manufacturing a wiring substrate according to claim 1, further comprising:
forming a wiring layer on the insulating layer including the convex portion.

3. The method for manufacturing a wiring substrate according to claim 1, wherein the adhesive sheet has a support film on a surface of the adhesive sheet such that the support film is releasable from the adhesive sheet, and the thermocompression bonding includes heating and pressing the adhesive sheet such that the convex portion has a surface covered with the support film.

4. The method for manufacturing a wiring substrate according to claim 1, further comprising:
forming a second insulating layer on the insulating layer,
wherein the forming of the second insulating layer includes forming a second convex portion overlapping the convex portion.

5. The method for manufacturing a wiring substrate according to claim 2, wherein the adhesive sheet has a support film on a surface of the adhesive sheet such that the support film is releasable from the adhesive sheet, and the thermocompression bonding includes heating and pressing the adhesive sheet such that the convex portion has a surface covered with the support film.

6. The method for manufacturing a wiring substrate according to claim 2, further comprising:
forming a second insulating layer on the insulating layer,
wherein the forming of the second insulating layer includes forming a second convex portion overlapping the convex portion.

7. The method for manufacturing a wiring substrate according to claim 3, further comprising:
forming a second insulating layer on the insulating layer,
wherein the forming of the second insulating layer includes forming a second convex portion overlapping the convex portion.

8. The method for manufacturing a wiring substrate according to claim 5, further comprising:
forming a second insulating layer on the insulating layer,
wherein the forming of the second insulating layer includes forming a second convex portion overlapping the convex portion.

9. The method for manufacturing a wiring substrate according to claim 1, wherein the adhesive sheet is thermocompression bonded to the substrate such that the insulating layer has a flat portion formed between the convex portion and the end surface of the insulating layer and that a height of the convex portion from the flat portion is 15 μm or less.

10. The method for manufacturing a wiring substrate according to claim 2, wherein the adhesive sheet is thermocompression bonded to the substrate such that the insulating layer has a flat portion formed between the convex portion and the end surface of the insulating layer and that a height of the convex portion from the flat portion is 15 μm or less.

11. A wiring substrate, comprising:
a first insulating layer; and
a second insulating layer formed on the first insulating layer,
wherein the first insulating layer has a circuit pattern region, a frame region surrounding the circuit pattern region, and a convex portion formed in the frame region such that the convex portion of the first insulating layer is not exposed from an end surface of the first insulating layer and that the second insulating layer is covering the convex portion of the first insulating layer.

12. The wiring substrate according to claim 11, wherein the second insulating layer has a second convex portion formed in the frame region such that the second convex portion is not exposed from the end surface of the first insulating layer and that the second convex portion is overlapping the convex portion of the first insulating layer.

13. The wiring substrate according to claim 11, further comprising:
a wiring layer formed between the first insulating layer and the second insulating layer such that the wiring layer is covering the convex portion of the first insulating layer entirely in the frame region of the first insulating layer.

14. The wiring substrate according to claim 12, further comprising:
a wiring layer formed on the second insulating layer; and
a solder resist formed on the second insulating layer such that the solder resist is covering the wiring layer and formed in a region surrounded by the second convex portion of the second insulating layer.

15. The wiring substrate according to claim 11, further comprising:
a wiring layer formed between the first insulating layer and the second insulating layer,
wherein the wiring layer has a mesh pattern in the frame region and between the convex portion and circuit pattern region of the first insulating layer.

16. The wiring substrate according to claim 12, further comprising:
a wiring layer formed between the first insulating layer and the second insulating layer such that the wiring layer is covering the convex portion of the first insulating layer entirely in the frame region of the first insulating layer.

17. The wiring substrate according to claim 12, further comprising:
a wiring layer formed between the first insulating layer and the second insulating layer,
wherein the wiring layer has a mesh pattern in the frame region of the first insulating layer and between the first convex portion and circuit pattern region of the first insulating layer.

18. The wiring substrate according to claim 13, wherein the wiring layer has a mesh pattern in the frame region of the first insulating layer and between the first convex portion and circuit pattern region of the first insulating layer.

19. The wiring substrate according to claim 16, wherein the wiring layer has a mesh pattern in the frame region of the first insulating layer and between the first convex portion and circuit pattern region of the first insulating layer.

20. The wiring substrate according to claim 11, wherein the first insulating layer has a flat portion formed between the convex portion and the end surface such that a height of the convex portion from the flat portion is 15 μm or less.
